(19) United States
(12) Patent Application Publication
(10) Pub. No.: US 2001/0046644 A1
(43) Pub. Date: Nov. 29, 2001

(54) Process for manufacturing information recording media and the information recording media

(76) Inventors: Takashi Ukachi, Ushiku (JP); Hideaki Takase, Kingston (CA); Takao Yashiro, Tsuchiura (JP)

Correspondence Address: LEYDIG VOIT & MAYER, LTD, TWO PRUDENTIAL PLAZA, SUITE 4900, 180 NORTH STETSON AVENUE, CHICAGO, IL, 60601-6780, US

(21) Appl. No.: 09/840,494

(22) Filed: Apr. 23, 2001

Related U.S. Application Data
(63) Continuation of application No. PCT/NL99/00611, filed on Oct. 1, 1999.

(30) Foreign Application Priority Data
Oct. 2, 1998 (JP) 10/281309

(51) Int. Cl. G03F 7/027; G03C 1/73

(52) U.S. Cl. 430/281.1; 430/273.1; 156/275.5; 156/275.7

(57) ABSTRACT

The invention relates to a process for manufacturing information recording media by adhering two disks, at least one of which possesses an information recording layer, wherein a radically polymerizable photocurable resin composition is put between the two disks and the resin composition is cured to adhere the disks by irradiating light from the external periphery edge and/or internal periphery edge of said disks, wherein the resin composition has a light absorbance of 12 or less at a wavelength of 360-45 nm.

### FIELD OF THE INVENTION

The present invention relates to a process for manufacturing information recording media by adhering two or more disks, at least one of which possesses an information recording layer, and more particularly to a process for manufacturing information recording media exhibiting superior durability, in which two or more disks can be efficiently adhered together in a short period of time irrespective of transparency of the substrate of the disks or the information recording layer.

### DESCRIPTION OF RELATED ART

Information recording media typified by a digital video (or versatile disk) (DVD) have conventionally been manufactured by adhering two disks, at least one of which possesses an information recording layer. When one of the two disks is transparent, a radically polymerizable photocurable resin composition has been used as an adhesive. In such a case, a radically polymerizable photocurable resin composition is put between the two disks. The disks are then exposed to light perpendicularly to the surface of the transparent disk, thereby curing the resin composition to adhere the disks.

On the other hand, when both disks are not transparent or are only scarcely transparent, two disks have conventionally been adhered using a hot-melt adhesive or a slow-curing photocurable composition which is polymerized by a cationic polymerization initiator.

In the manufacture of disks using a hot-melt adhesive, a melted adhesive is applied to either one or both of the disks. The two disks are put together while heating the disks at a melting point of the adhesive and then cooled to solidify the adhesive.

The process using such a hot-melt adhesive requires steps of melting the adhesive and solidifying the melted adhesive. Distortion of the substrates caused by a process of heating, cooling, and solidification and warping caused by the difference in a coefficient of thermal expansion between the substrate and the adhesive can not be disregarded. These problems make it difficult to constantly manufacture high quality information recording media with high production efficiency. In addition, the hot-melt adhesive between the disks melts out of the space between the disks when the disks are heated at a temperature close to the melting point of the adhesive. This causes a serious damage to the disk and might even destroy it completely.

In the manufacture of disks using a slow-curing cationically polymerizable photocurable composition, such a composition is applied to either one or both disks, and exposed to light to cure to some extent. Then, the two disks are superposed and the composition is completely cured by the cationic polymerization reaction without irradiating light using a cationic polymerization photo-initiator.

The problem with a process using a slow-curing cationically polymerizable photocurable resin composition, on the other hand, is the time needed to prepare the disk. Several minutes to ten minutes are required to complete the curing reaction using a cationic polymerization photo-initiator. The process of making information recording media using a cationically polymerizable photocurable resin composition is much slower than the process using a radically polymerizable photocurable resin composition. Moreover, since products with a specified quality cannot be obtained unless two disks are held completely fixed for several to ten minutes, a special device to secure the disks is needed.

Therefore, an object of the present invention is to provide a process for efficiently manufacturing information recording media with superior quality in a short period of time, also for the case that none of the disks are transparent.

Furthermore it is an object of the invention to provide an adhesive which can be used advantageously in the manufacture of information recording media.

### SUMMARY OF THE INVENTION

The inventors of the present invention discovered that if a radically polymerizable photocurable resin composition with a high curing speed having a light absorbance of 12.0 or less, at a wavelength region from 360 nm to 450 nm, is used as an adhesive and light is irradiated from the external periphery edge and/or internal periphery edge of the two disks, the composition cures rapidly at a constant rate, whereby high quality information recording media are extremely advantageously produced on an industrial scale. Preferably, the radically polymerizable photocurable resin composition of the present invention contains a photoinitiator with a large molar extinction coefficient at a wavelenght in the range from 400 to 450 nm. More preferably the resin composition also contains another photoinitiator with a small molar extinction coefficient in the same wavelength range which produces an adhesive for optical disks which exhibits superior deep curability and does not leave viscous materials around the edge of irradiated area. Such an adhesive can ensure efficient manufacture of high-quality information recording media in a short time, even if two sheet of disks to be adhered are incapable of transmitting light.

### BRIEF DESCRIPTION OF THE DRAWINGS

FIG. 1 is a schematic diagram of the method for irradiating UV light from outside of the periphery edge of two disks.

FIG. 2 is a cross sectional schematic diagram when UV light is irradiated from outside the periphery edge of two disks.

### DETAILED DESCRIPTION OF THE INVENTION

The two or more disks can be used in the process of the present invention. Of these disks one or more disks have an information recording layer. Such a disk having an information recording layer preferably is an optical disk which comprises a substrate made from a commonly known plastic provided with microscopic pits corresponding to the recorded information on one side and a light reflecting layer laminated on the substrate. Alternatively, such a disk may be a writable optical disk comprising a plastic substrate with a recordable layer containing a dye on which a light reflecting layer is laminated. Suitable examples of plastics for the substrate, include thermoplastic resins such as an acrylic resin, polycarbonate, and amorphous polyolefin resin.

The light reflecting layer, is a layer applied to read the recorded information. Such layer can reflect visible rays at a high rate and can precisely confirm the above-mentioned microscopic pits. Suitable examples include aluminum, nickel, silver, gold, silicon nitride, silicon carbide, and the like.

The disk used in the present invention can be made by fabricating the above-mentioned plastic material for the substrate into a stamper in which grooves corresponding to the information such as sound and images are engraved by cast molding, and laminating light reflecting layer thereon. The lamination can be carried out by producing a metallic thin layer with a prescribed thickness by vapor deposition (pit formation). The information recording layer in which the above-mentioned grooves and layers are integrated can be obtained in this manner.

In the case of the writable optical information recording media, a recording layer containing an organic coloring compound such as a cyanine compound or a phthalocyanine compound is formed on the substrate instead of producing physical microscopic pits on the substrate. A reflecting layer made of a thin metal layer is then formed on this recording layer by the same method as mentioned above.

In the present invention, each recording layer of the two disks is preferably recorded with individual information or continuous information.

Because the radically polymerizable photocurable resin composition must rapidly cure when irradiated with light from the external periphery edge and/or internal periphery edge of the disk, such a composition must have a light absorbance of of 12.0 or less, preferably 10.0 or less, and more preferably 9.0 or less, at a wavelength region from 360 nm to 450 nm. The absorbance here is a value measured using a 1 cm thick cell. This can be achieved by proper selection of the materials used in the adhesive of the present invention. In particular a proper selection of photoinitiators, UV-absorbers, light stabilizers and aging preventives is necessary to keep the absorbance below 12 or less.

The preferred radically polymerizable photocurable resin composition which is used as the adhesive in the present invention preferably contains an oligomer, reactive diluent at least one photoinitiator and optionally at least one additive. Preferably at least one photoinitiator is used having a large molar extinction coefficient at a wavelenght in the range from 400 to 450 nm.

Preferably the composition also contains another photoinitiator with a small molar extinction coefficient in the same wavelenght range.

The present inventors have found that the combined use of a photoinitiator with a large molar extinction coefficient at a wavelenght in the range from 400 to 450 nm and another photoinitiator with a small molar extinction coefficient in the same wavelength range produces an adhesive for optical disks which exhibits superior deep curability and does not leave viscous materials around the edge of irradiated area. Such an adhesive is particularly preferred because it can ensure efficient manufacture of high-quality information recording media in a short time.

In a preferred embodiment of the present invention the adhesive for optical disks comprises: (A) a photoinitiator having a molar extinction coefficient of 50 (l/mol cm) or more at a wavelenght in the range from 400 to 450 nm, and (B) a photoinitiator having a molar extinction coefficient of 1 (l/mol cm) or less at a wavelenght in the range from 400 to 450 nm.

The component (A) used in the adhesive of the present invention for optical disks is a photoinitiator having a molar extinction coefficient of 50 (l/mol cm) or more, and preferably 100 (l/mol cm) or more, at a wavelenght in the range from 400 to 450 nm in acetonitrile. In addition, the component (A) is capable of absorbing light in the ultraviolet region. Suitable examples of the component (A) having such characteristics include bis (2,4,6-trimethylbenzoyl)phenylphosphineoxide, 2,4,6-trimethylbenzoyldiphenylphosphineoxide, thioxanethone diethylthioxanthone, 2-isopropylthioxanthone, 2-chlorothioxanthone, and the like. As commercially available products, IRGACURE 819 (manufactured by Ciba Specialty Chemicals Co., Ltd), Lucirin TPO, LR8893 (manufactured by BASF), KAYACURE ITX, DETX (manufactured by Nippon Kayaku Co., Ltd.), and the like can be given. Among these, 2,4,6-trimethylbenzoyldiphenylphosphineoxide is particularly preferred.

The component (B) is a photoinitiator having a molar extinction coefficient of 1 (l/mol cm) or less, and preferably 0.5 (l/mol cm) or less, at a wavelenght in the range from 400 to 450 nm in acetronitrile. In addition, the component (B) is capable of absorbing light in the ultraviolet region. Given as examples the component (B) having such characteristics are 1-[4-(2-hydroxyethoxy)-phenyl]-2-hydroxy-2-methylpropan-1-one, 1-hydroxycyclohexyl phenyl ketone, 2,2-dimethoxy-1,2-diphenylethane-1-on, 2-hydroxy-2-methyl-1-phenylpropan-1-one, oligo(2-hydroxy-2-methyl-1-[4-(1-methylvinyl)phenyl]propanone, and the like. As commercially available products, IRGACURE 2959, 184, 651, DAROCURE 1173 (manufactured by Ciba Specialty Chemicals Co. Ltd.), ESACURE KIP-100F, KIP150 (manufactured by Lamberti Co.), and the like can be given. Among these, 1-[4-(2-hydroxyethoxy)phenyl]-2-hydroxy-2-methyl-1-propane-1-on is particularly preferred.

To ensure improved deep curability, the component (A) is preferably added in an amount from 0.001 to 1 wt %, and more preferably from 0.01 to 0.5 wt %, to the adhesive for optical disks of the present invention. To avoid presence of viscous materials around edges of irradiated area, the component (B) is preferably added in an amount from 0.1 to 20 wt %, and more preferably from 0.5 to 10 wt %, to the adhesive for optical disks of the present invention.

As an oligomer, urethane (meth)acrylates, and the like can be given.

A urethane (meth)acrylate can be prepared by reacting a polyol compound, a polyisocyanate compound, and a hydroxyl group-containing (meth)acrylate compound.

As typical polyol compounds used in the present invention, polyether polyols, polyester polyols, polycarbonate polyols, polycaprolactone polyols, aliphatic hydrocarbons having two or more hydroxyl groups in the molecule, alicyclic hydrocarbons having two or more hydroxyl groups in the molecule, unsaturated hydrocarbons having two or more hydroxyl groups in the molecule, and the like can be given. These polyol compounds can be used either individually or in combinations of two or more.

As the above-mentioned polyether polyols, aliphatic polyether polyols, alicyclic polyether polyols, and aromatic polyether polyols can be given.

Given as examples of aliphatic polyether polyols are polyhydric alcohols such as polyethylene glycol, polypropylene glycol, polytetramethylene glycol, polyhexamethylene glycol, polyheptamethylene glycol, polydecamethylene glycol, pentaerythritol, dipentaerythritol, trimethylolpropane; alkylene oxide addition polyols such as ethoxylated triol of trimethylolpropane, propoxylated triol of trimethylolpropane, ethoxylated-propoxylated triol of trimethylolpropane, ethoxylated tetraol of pentaerythritol, and ethoxylated hexaol of dipentaerythritol; and polyether polyols obtained by the ring-opening polymerization of two or more ion-polymerizable cyclic compounds.

As examples of alicyclic polyether polyols, alkylene oxide addition diol of hydrogenated bisphenol A, alkylene oxide addition diol of hydrogenated bisphenol F, alkylene oxide addition diol of 1,4-cyclohexanediol, and the like can be given.

As examples of aromatic polyether polyols, alkylene oxide addition diol of bisphenol A, alkylene oxide addition diol of bisphenol F, alkylene oxide addition diol of hydroquinone, alkylene oxide addition diol of naphthohydroquinone, alkylene oxide addition diol of anthrahydroquinone, and the like can be given.

These polyether polyols are commercially available. Given as examples of commercially available aliphatic polyether polyols are PTMG 650, PTMG 1000, PTMG 2000 (manufactured by Mitsubishi Chemical Corp.), PPG 1000, EXCENOL 1020, EXCENOL 2020, EXCENOL 3020, EXCENOL 4020 (manufactured by Asahi Glass Co., Ltd.), PEG 1000, Unisafe DC 1100, Unisafe DC 1800, Unisafe DCB 1100, Unisafe DCB 1800 (manufactured by Nippon Oil and Fats Co., Ltd.), PPTG 1000, PPTG 2000, PPTG 4000, PTG 400, PTG 650, PTG 2000, PTG 3000, PTGL 1000, PTGL 2000 (manufactured by Hodogaya Chemical Co., Ltd.), Z-3001-4, Z-3001-5, PBG 2000, PBG 2000B (manufactured by Daiichi Kogyo Seiyaku Co., Ltd.), TMP30, PNT4 Glycol, EDA P4, EDA P8 (manufactured by Nippon Nyukazai Co., Ltd.), and Quadrol (manufactured by Asahi Denka Kogyo K.K.). Given as commercially available aromatic polyether polyols are Uniol DA400, DA700, DA1000, DB400 (manufactured by Nippon Oil and Fats Co., Ltd.), and the like.

The above-mentioned polyester polyols can also be manufactured by the reaction of a polyhydric alcohol and a polybasic acid. Here, given as examples of polyhydric alcohols are ethylene glycol, polyethylene glycol, propylene glycol, polypropylene glycol, tetramethylene glycol, polytetramethylene glycol, 1,4-butanediol, 1,5-pentanediol, 1,6-hexanediol, 1,7-heptanediol, 1,8-octanediol, neopentyl glycol, 1,4-cyclohexanediol, 1,4-cyclohexanedimethanol, 1,2-bis(hydroxyethyl)cyclohexane, 2,2-diethyl-1,3-propanediol, 3-methyl-1,5-pentanediol, 1,9-nonanediol, 2-methyl-1,8-octanediol, glycerol, trimethylolpropane, ethoxylated compound of trimethylolpropane, propoxylated compound of trimethylolpropane, ethoxylated-propoxylated compound of trimethylolpropane, sorbitol, pentaerythritol, dipentaerythritol, alkylene oxide addition polyols, and the like. As examples of polybasic acids, phthalic acid, isophthalic acid, terephthalic acid, maleic acid, fumaric acid, adipic acid, sebacic acid, and the like can be given. As commercially available products of these polyester polyols, Kurapol P1010, Kurapol P2010, PMIPA, PKA-A, PKA-A2, PNA-2000 (manufactured by Kuraray Co., Ltd.), and the like can be given.

As examples of the above-mentioned polycarbonate polyols, polycarbonate diols shown by the following formula (1) can be given.

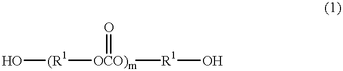

wherein R¹ is an alkylene group having 2-20 carbon atoms, a (poly)ethylene glycol residual group, (poly)propylene glycol residual group, or (poly) tetramethylene glycol residual group, and m is an integer from 1-30.

Given as specific examples of R¹ are residual groups obtained after removal of both terminal hydroxyl groups from the following compounds: 1,4-butanediol, 1,5-pentanediol, neopentyl glycol, 1,6-hexanediol, 1,4-cyclohexanedimethanol, 1,7-heptanediol, 1,8-octanediol, 1,9-nonanediol, ethylene glycol, diethylene glycol, triethylene glycol, tetraethylene glycol, propylene glycol, dipropylene glycol, tripropylene glycol, tetrapropylene glycol, and the like.

These polycarbonate polyols are also commercially available under the trade names such as N-980, N-981, N-982, N-983 (manufactured by Nippon Polyurethane Industry, Co., Ltd.), PC-8000 (manufactured by PPG), PNOC 1000, PNOC 2000, PMC 1000, PMC 2000 (manufactured by Kuraray Co., Ltd.), and PLACCEL CD-205, CD-208, CD-210, CD-220, CD-205PL, CD-208PL, CD-210PL, CD-220PL, CD-205HL, CD-208HL, CD-210HL, CD-220HL, CD-210T, CD-221T (manufactured by Daicel Chemical Industries, Ltd.).

As the above-mentioned polycaprolactone polyols, polycaprolactone diols obtained by the addition reaction of ε-caprolactone and diols such as ethylene glycol, polyethylene glycol, propylene glycol, polypropylene glycol, tetramethylene glycol, polytetramethylene glycol, 1,2-polybutylene glycol, 1,6-hexanediol, neopentyl glycol, 1,4-cyclohexanedimethanol, and 1,4-butanediol can be given. As examples of commercially available products of these polycaprolactone polyols, PLACCEL 205, 205AL, 212, 212AL, 220, 220AL (manufactured by Daicel Chemical Industries, Ltd.), and the like can be given.

As examples of aliphatic hydrocarbons having two or more hydroxyl groups in the molecule, ethylene glycol, propylene glycol, tetramethylene glycol, 1,4-butanediol, 1,5-pentanediol, 1,6-hexanediol, 1,7-heptanediol, 1,8-octanediol, 1,9-nonanediol, neopentyl glycol, 2,2-diethyl-1,3-propanediol, 3-methyl-1,5-pentanediol, 2-methyl-1,8-octanediol, hydrogenated polybutadiene having terminal hydroxyl groups, glycerol, trimethylolpropae, pentaerythritol, and sorbitol can be given.

As examples of alicyclic hydrocarbons having two or more hydroxyl groups in the molecule, 1,4-cyclohexanediol, 1,4-cyclohexanedimethanol, 1,2-bis(hydroxyethyl)cyclohexane, dimethylol compounds of dicyclopentadiene, and tricyclodecanedimethanol can be given.

As examples of unsaturated hydrocarbons having two or more hydroxyl groups in the molecule, polybutadiene having terminal hydroxyl groups, polyisoprene having terminal hydroxyl groups, and the like can be given.

Polyols other than those mentioned above, such as β-methyl-δ-valerolactonediol, castor oil, modified castor oil, terminal diol compound of polydimethylsiloxane, and carbitol-modified polydimethylsiloxane diol can also be used.

The number average molecular weight of these polyol compounds is preferably in the range from 50 to 15000, and particularly preferably from 100 to 8000.

As the above-mentioned polyisocyanate compounds, diisocyanate compounds are preferable. The following compounds can be given as examples of such diisocyanate compounds: 2,4-tolylene diisocyanate, 2,6-tolylene diisocyanate, 1,3-xylylene diisocyanate, 1,4-xylylene diisocyanate, 1,5-naphthalene diisocyanate, m-phenylene diisocyanate, p-phenylene diisocyanate, 3,3′-dimethyl-4,4′-diphenylmethane diisocyanate, 3,3′-dimethylphenylene diisocyanate, 4,4′-biphenylene diisocyanate, 1,6-hexane diisocyanate, isophorone diisocyanate, 2,2,4-trimethylhexamethylene diisocyanate, bis(2-isocyanatethyl) fumarate, 6-isopropyl-1,3-phenyl diisocyanate, 4-diphenylpropane diisocyanate, lysine diisocyanate, hydrogenated diphenylmethane diisocyanate, hydrogenated xylylene diisocyanate, and tetramethyl xylylene diisocyanate. Of these, 2,4-tolylene diisocyanate, 2,6-tolylene diisocyanate, hydrogenated xylylene diisocyanate, isophorone diisocyanate, hydrogenated diphenylmethane diisocyanate, and the like are particularly preferable. These diisocyanate compounds can be used either individually or in combinations of two or more.

The hydroxyl group-containing (meth)acrylate compounds are (meth)acrylates having a hydroxyl group on the ester residual group, for example, 2-hydroxyethyl (meth)acrylate, 2-hydroxypropyl (meth)acrylate, 4-hydroxybutyl (meth)acrylate, 2-hydroxy-3-phenyloxypropyl (meth)acrylate, 1,4-butanediol mono(meth)acrylate, 2-hydroxyalkyl (meth)acryloylphosphate, 4-hydroxycyclohexyl (meth)acrylate, 1,6-hexanediol mono(meth)acrylate, neopentyl glycol mono(meth)acrylate, trimethylolpropane di(meth)acrylate, trimethylolethane di(meth)acrylate, pentaerythritol tri(meth)acrylate, dipentaerythritol penta(meth)acrylate, and (meth)acrylates shown by the following formula (2)can be given:

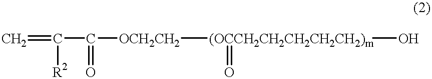

wherein R² represents a hydrogen atom or a methyl group and n indicates an integer from 1 to 15, and preferably from 1 to 4. The compounds obtained by the addition reaction of a glycidyl group-containing compound such as an alkyl glycidyl ether, allyl glycidyl ether, or glycidyl (meth)acrylate and (meth)acrylic acid can also be given. Of these compounds, 2-hydroxyethyl (meth)acrylate, 2-hydroxypropyl (meth)acrylate, 4-hydroxybutyl (meth)acrylate, and the like are particularly preferable.

Although there are no specific limitations to the method for synthesizing the urethane (meth)acrylate of the present invention, the following methods (i) to (iii) can be given as typical examples. (i) A method of reacting the polyisocyanate (b) and the hydroxyl group-containing (meth)acrylate (c), and reacting the resulting product with the polyol (a). (ii) A method of reacting all of the polyol (a), polyisocyanate (b), and hydroxyl group-containing (meth)acrylate (c) altogether. (iii) a method of reacting the polyol (a) and the polyisocyanate (b), and reacting the resulting product with the hydroxyl group-containing (meth)acrylate (c).

In the synthesis of the urethane (meth)acrylate, it is preferable to use a urethanization catalyst such as copper naphthenate, cobalt naphthenate, zinc naphthenate, di-n-butyl tin dilaurate, triethylamine, 1,4-diazabicyclo[2.2.2]octane, or 1,4-diaza-2-methylbicyclo[2.2.2]octane in an amount from 0.01 to 1 part by weight for 100 parts by weight of the reaction product. The reaction temperature is usually from 0 to 90° C., and preferably from 10 to 80° C.

The number average molecular weight of the urethane (meth)acrylate is preferably in the range from 400 to 40000, and particularly preferably from 600 to 20000.

As the reactive diluent used in the present invention, (meth)acrylate compounds having at least one (meth)acryloyl group in the molecule can be given. Included in such a reactive diluent are monofunctional compounds having only one (meth)acryloyl group and polyfunctional compounds having two or more (meth)acryloyl groups. These can be used in combination at an appropriate proportion.

The following compounds can be given as examples of the monofunctional compounds: methyl (meth)acrylate, ethyl (meth)acrylate, propyl (meth)acrylate, isopropyl (meth)acrylate, butyl (meth)acrylate, amyl (meth)acrylate, isobutyl (meth)acrylate, t-butyl (meth)acrylate, pentyl (meth)acrylate, isoamyl (meth)acrylate, hexyl (meth)acrylate, heptyl (meth)acrylate, octyl (meth)acrylate, isooctyl (meth)acrylate, 2-ethylhexyl (meth)acrylate, nonyl (meth)acrylate, decyl (meth)acrylate, isodecyl (meth)acrylate, undecyl (meth)acrylate, dodecyl (meth)acrylate, lauryl (meth)acrylate, octadecyl (meth)acrylate, stearyl (meth)acrylate, tetrahydrofurfuryl (meth)acrylate, butoxyethyl (meth)acrylate, ethoxydiethylene glycol (meth)acrylate, benzyl (meth)acrylate, cyclohexyl (meth)acrylate, phenoxyethyl (meth)acrylate, polyethylene glycol mono(meth)acrylate, polypropylene glycol mono(meth)acrylate, methoxyethylene glycol mono(meth)acrylate, ethoxyethyl (meth)acrylate, ethoxyethoxyethyl (meth)acrylate, methoxypolyethylene glycol (meth)acrylate, methoxypolypropylene glycol (meth)acrylate, dicyclopentadienyl (meth)acrylate, dicyclopentanyl (meth)acrylate, dicyclopentenyl (meth)acrylate, tricyclodecanyl (meth)acrylate, bornyl (meth)acrylate, isobornyl (meth)acrylate, adamantyl (meth)acrylate, dimethylaminoethyl (meth)acrylate, diethylaminoethyl (meth)acrylate, 7-amino-3,7-dimethyloctyl (meth)acrylate, (meth)acryloyl morpholine, 2-(meth)acryloyloxyethyl phthalic acid, 2-(meth)acryloyl oxyethylhexahydro phthalic acid, 2-(meth)acryloyloxypropylphthalic acid, 2-(meth)acryloyloxypropyltetrahydrophthalic acid, 2-(meth)acryloyloxypropylhexahydrophthalic acid, 2-(meth)acryloyloxyethylsuccinic acid, trifluoroethyl (meth)acrylate, tetrafluoropropyl (meth)acrylate, hexafluoropropyl (meth)acrylate, octafluoropentyl (meth)acrylate, heptadecafluorodecyl (meth)acrylate, mono[2-(meth)acryloyloxyethyl]phosphate, mono[2-(meth)acryloyloxyethyl]diphenyl phosphate, mono[2-(meth)acryloyloxypropyl]phosphate, and compounds shown by the following formulas (3) to (5):

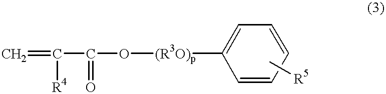

wherein R³ is an alkylene group or hydroxyalkylene group having 2 to 6 carbon atoms, R⁴ is a hydrogen atom or a methyl group, R⁵ is a hydrogen atom or an alkyl group having 1 to 12 carbon atoms, and p is an integer from 0 to 20, preferably from 1-8

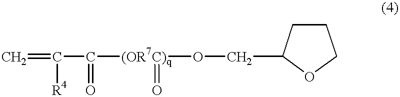

wherein R⁶ is a hydrogen atom or a methyl group, and R⁷ is an alkylene group having 2 to 8 carbon atoms, and q is an integer from 0 to 8.

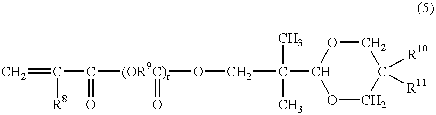

wherein R⁸ is a hydrogen atom or a methyl group, R⁹ is an alkylene group having 2 to 8 carbon atoms, r is an integer from 0 to 8, and R¹⁰ and R¹¹ are individually a hydrogen atom or an alkyl group having 1 to 6 carbon atoms.

Given as examples of commercially available products of these monofunctional compounds are Aronix M101, M102, M110, M111, M113, M114, M117, M120, M152, M154, M5300, M5400, M5500, M5600 (manufactured by Toagosei Co., Ltd.), KAYARAD TC-110S, R-128H, R629, R644 (manufactured by Nippon Kayaku Co., Ltd.), IPAA, AIB, SBAA, TBA, IAAA, HEXA, CHA, NOAA, IOAA, INAA, LA, TCDA, MSAA, CAA, HDAA, LTA, STA, ISAA-1, ODAA, NDAA, IBXA, ADAA, TDA, 2-MTA, DMA, Viscoat #150, #150D, #155, #158, #160, #190, #190D, #192, #193, #220, #320, #2311HP, #2000, #2100, #2150, #2180, MTG (manufactured by Osaka Organic Chemical Industry Co., Ltd.), NK Ester M-20G, M-40G, M-90G, M-230G, CB-1, SA, S, AMP-10G, AMP-20G, AMP-60G, AMP-90G, A-SA, NLA (manufactured by Shin-Nakamura Chemical Co., Ltd.), ACMO (manufactured by Kojin Co., Ltd.), Light Acrylate IA-A, L-A, S-A, BO-A, EC-A, MTG-A, DPM-A, PO-A, P-200A, THF-A, IB-XA, HOA-MS, HOA-MPL, HOA-MPE, HOA-HH, IO-A, BZ-A, NP-EA, NP-1OEA, HOB-A, FA-108, Epoxy Ester M-600A, Light Ester P-M (manufactured by Kyoeisha Chemical Co., Ltd.), FA-511, FA-512A, FA-513A (manufactured by Hitachi Chemical Co., Ltd.), AR-100, MR-100, MR-200, MR-260 (manufactured by Daihachi Chemical Co., Ltd.), and JAMP-100, JAMP-514, JPA-514 (manufactured by Johoku Chemical Co., Ltd.).

The following compounds are given as examples of the above-mentioned polyfunctional compounds: hydroxyalkyl (meth)acrylate, ethylene glycol di(meth)acrylate, propylene glycol di(meth)acrylate, 1,4-butanediol di(meth)acrylate, 1,6-hexanediol di(meth)acrylate, 1,9-nonanediol di(meth)acrylate, diethylene glycol di(meth)acrylate, triethylene glycol di(meth)acrylate, tetraethylene glycol di(meth)acrylate, polyethylene glycol di(meth)acrylate, dipropylene glycol di(meth)acrylate, tripropylene glycol di(meth)acrylate, polypropylene glycol di(meth)acrylate, neopentyl glycol di(meth)acrylate, hydroxypivalic acid neopentyl glycol di(meth)acrylate, trimethylolpropane tri(meth)acrylate, pentaerythritol tri(meth)acrylate, pentaerythritol tetra(meth)acrylate, ditrimethylolpropane tetra(meth)acrylate, dipentaerythritol penta(meth)acrylate, dipentaerythritol hexa(meth)acrylate, trimethylolpropanetrioxyethyl (meth)acrylate, trimethylolpropanepolyoxyethyl (meth)acrylate, trimethylolpropanetrioxypropyl (meth)acrylate, trimethylolpropanepolyoxyethyl (meth)acrylate, tris (2-hydroxyethyl)isocyanurate di(meth)acrylate, tris(2-hydroxyethyl)isocyanurate tri(meth)acrylate, ethoxylated bisphenol A di(meth)acrylate, ethoxylated bisphenol F di(meth)acrylate, propoxylated bisphenol A di(meth)acrylate, propoxylated bisphenol F di(meth)acrylate, tricyclodecanedimethanol di(meth)acrylate, bisphenol A diepoxy di(meth)acrylate, bisphenol F diepoxy di(meth)acrylate, bis[2-(meth)acryloyloxyethyl]phosphate, bis[2-(meth)acryloyloxypropyl]phosphate, and tris[2-(meth)acryloyloxethyl]phosphate.

Given as commercially available products of these polyfunctional compounds are SA-1002, SA-2006, SA-2007, SA-4100, SA-5001, SA-6000, SA-7600, SA-8000, SA-9000 (manufactured by Mitsubishi Chemical Corp.), Viscoat #195, #195D, #214HP, #215, #215D, #230, #230D, #260, #295, #295D, #300, #310HP, #310HG, #312, #335HP, #335D, #360, GPT, #400, V#540, #700 (manufactured by Osaka Organic Chemical Industry Co., Ltd.), KAYARAD MANDA, R-526, NPGDA, PEG400DA, R-167, HX-220, HX-620, R-551, R-712, R-604, R-684, GPO-303, TMPTA, THE-330, TPA-320, TPA-330, PET-30, RP-1040, T-1420, DPHA, D-310, D-330, DPCA-20, DPCA-30, DPCA-60, DPCA-120 (manufactured by Nippon Kayaku Co., Ltd.), Aronix M-210, M-208, M-215, M-220, M-225, M-233, M-240, M-245, M-260, M-270, M-305, M-309, M-310, M-315, M-320, M-350, M-360, M-400, M-408, M-450 (manufactured by Toagosei Co., Ltd.), SR-212, SR-213, SR-355 (manufactured by Sartomer Co., Ltd.), SP-1506, SP-1507, SP-1509, SP-1519-1, SP-1563, SP-2500, VR60, VR77, VR90 (manufactured by Showa Highpolymer Co., Ltd.), Light Ester P-2M (manufactured by Kyoeisha Chemical Co., Ltd.), Viscoat 3PA (manufactured by Osaka Organic Chemical Industry Co., Ltd.), EB-169, EB-179, EB-3603, R-DX63182 (manufactured by Daicell UCB Co., Ltd.) As reactive diluents, radically polymerizable compounds other than those containing an acrylic group, for example, N-vinylpyrrolidone, N-vinylcaprolactam, vinylacetate, vinylpropionate, styrene, divinylbenzene, and unsaturated polyester can be given. The above-mentioned unsaturated polyester is an ester of a dicarboxylic acid which possesses a radically polymerizable unsaturated double bond and an alcohol. Maleic anhydride, itaconic acid, fumaric acid, and the like can be given as the dicarboxylic acid which possesses radically polymerizable unsaturated double bond. As alcohols, monohydric alcohols such as methanol, ethanol, n-propyl alcohol, isopropyl alcohol, n-butyl alcohol, isobutyl alcohol, sec-butyl alcohol, tert-butyl alcohol, n-hexanol, cyclohexanol, and 2-ethylhexyl alcohol; (poly)ethylene glycols such as ethylene glycol, diethylene glycol, and triethylene glycol; (poly)propylene glycols such as propylene glycol, dipropylene glycol, and tripropylene glycol; dihydric alcohols such as 1,6-hexanediol; and trihydric alcohols such as glycerol and trimethylolpropane can be given.

Notwithstanding the preferred embodiment using specific photoinitiators as described above, one or more photoinitiators can be used as listed below, providing that the absorbance of the composition is less than 12.

The following compounds can be given as examples of photo-initiators:

2,2-dimethoxy-1,2-diphenylethan-1-one, 2-hydroxy-2-methyl-1-phenyl-propan-1-one, 1-hydroxy-cyclohexyl phenyl ketone, 3-methylacetophenone, 2,2-dimethoxy-2-phenylacetophenone, xanthone, fluorenone, benzaldehyde, fluorene, anthraquinone, triphenylamine, carbazole, 3-methylacetophenone, benzophenone, 4-chlorobenzophenone, 4,4′-dimethoxybenzophenone, 4,4′-diaminobenzophenone, benzoinethyl ether, benzoinpropyl ether, Michler's ketone, benzyl methyl ketal, 1-(4-isopropylphenyl)-2-hydroxy-2-methylpropan-1-one, 1-(4-dodecylphenyl)-2-hydroxy-2-methylpropan-1-one, 4-(2- hydroxyethoxy)phenyl-(2-hydroxy-2-propyl) ketone, 2-methyl-1-[4-(methylthio)phenyl]-2-morpholino-propan-1-one, 2,4,6-trimethylbenzoylphenylphosphinate, 2,4,6-trimethylbenzoyldiphenylphosphine oxide, 2-benzyl-2-dimethylamino-1-(4-morpholinophenyl)-butan-1-one, bis(2,6-dimethoxybenzoyl)-2,4,4-trimethylpentylphosphine oxide, methyl benzoyl formate, thioxanethone, diethylthioxanthone, 2-isopropylthioxanthone, 2-chlorothioxanthone, and oligo[2-hydroxy-2-methyl-1-[4-(1-methylvinyl)phenyl]propanone].

As the commercially available products of these photoinitiators, IRGACURE 184, 261, 369, 819, 907, CGI-403, 819, 1700, 1800, 1850, Darocur 953, 1116, 1664, 2273, 2959, ZL 13331 (manufactured by Ciba Specialty Chemicals Co., Ltd.), Lucirin TPO, LR8893 (manufactured by BASF), Ubecryl P36 (manufactured by UCB), VICURE55 (manufactured by Akzo), ESACURE KIP 100F, KIP 150 (manufactured by Lamberti), KAYAKUREI TX, QTX, DETX, BMS (manufactured by Nippon Kayaku Co., Ltd.[I.A1]), and the like can be given.

In addition to the above components, additives can be incorporated in the composition of the present invention. Such additives may be epoxy resin, polyamide, polyamideimide, polyurethane, polybutadiene, chloroprene, polyether, polyester, pentadiene derivatives, SBS (styrene/butadiene/styrene block copolymer), hydrogenated SBS, SIS (styrene/isoprene/styrene block copolymer), petroleum resin, xylene resin, ketone resin, fluorine-containing oligomer, silicon-containing oligomer, polysulfide-type oligomer, and the like.

More in particular, cationic curable components can be used in addition to the radical curable components. Such cationic curable components comprise e.g. epoxy group containing compounds and at least one cationic photoinitiator. Combined radical and cationic curable systems are also called hybrid systems, which are known by the man skilled in the art.

Moreover, various paint additives other than the above-mentioned additives can optionally be added to the composition of the present invention. Such additives include antioxidants, UV absorbers, light stabilizers, aging preventives, silane coupling agents, antifoaming agents, leveling agents, antistatic agents, surfactants, preservatives, heat polymerization inhibitors, plasticizers, wettability improvers, and the like. Care should be taken to either not use additives that absorb light in the region of 360-450 nm, or to use these in sufficient low quantities (generally less than 1 wt %, preferably less than 0.5 wt % and more preferably less than 0.2 wt %) that the absorbtion is kept below 12 or less as required by the present invention.

Suitable examples of antioxidant include Irganox 245, 259, 565, 1010, 1035, 1076, 1081, 1098, 1222, 1330 (manufactured by Ciba Specialty Chemicals Co., Ltd.).

As UV absorbers, benzotriaole-type and triazine-type UV absorbers can be given. As commercially available products of such UV absorbers, Tinuvin P, 234, 320, 326, 327, 328, 213, 400 (manufactured by Ciba Specialty Chemicals Co., Ltd.), Sumisorb 110, 130, 140, 220, 250, 300, 320, 340, 350, 400 (manufactured by Sumitomo Chemical Industries Co., Ltd.), and the like are given.

As light stabilizers, Tinuvin 144, 292, 622LD (manufactured by Ciba Specialty Chemicals Co., Ltd.) Sanol LS440, LS770 (manufactured by Sankyo Co., Ltd.), Sumisorb TM-061 (manufactured by Sumitomo Chemical Industries Co., Ltd.), and the like can be given.

Phenol-type, allyl amine-type, ketone amine-type aging preventives, and the like can be given as aging preventives. Commercially available products of these aging preventives are Antigene W, S, P, 3C, 6C, RD-G, FR, AW (manufactured by Sumitomo Chemical Industries Co., Ltd.), and the like.

As silane coupling agents, the following compounds can be given:

γ-mercaptopropylmethylmonomethoxysilane, γ-mercaptopropylmethyldimethoxysilane, γ-mercaptopropyltrimethoxysilane, γ-mercaptopropylmonoethoxysilane, γ-mercaptopropyldiethoxysilane, γ-mercaptopropyltriethoxysilane, β-mercaptoethylmonoethoxysilane, β-mercaptoethyltriethoxysilane, β-mercaptoethyltriethoxysilane, N-(2-aminoethyl)-3-aminopropylmethyldimethoxysilane, N-(2-aminoethyl)-3-aminopropyltrimethoxysilane, γ-aminopropyltriethoxysilane, γ-glycidoxypropyltrimethoxysilane, γ-glycidoxypropylmethyldimethoxysilane, 2-(3,4-epoxycyclohexyl)ethyltrimethoxysilane, γ-chloropropylmethyldimethoxysilane, γ-chloropropyltrimethoxysilane, and γ-methaacryloyloxypropyltrimethoxysilane. As commercially available products of these silane coupling agents, Sila-Ace S310, S311, S320, S321, S330, S510, S520, S530, S610, S620, S710, S810 (manufactured by Chisso Corp.), SH6062, AY43-062, SH6020, SZ6023, SZ6030, SH6040, SH6076, SZ6083 (manufactured by Toray-Dow Corning Silicone Co., Ltd.), KBM403, KBM503, KBM602, KBM603, KBM803, KBE903 (manufactured by Shin-Etsu Silicone Co., Ltd.), and the like can be given.

As examples of antifoaming agents, organic copolymers containing no Si or F atoms such as Flowlen AC-202, AC-300, AC-303, AC-326F, AC-900, AC-1190, AC-2000 (manufactured by Kyoeisha Chemical Co., Ltd.); silicon-type antifoaming agents such as Flowlen AC-901, AC-950, AC-1140, AO-3, AO-4OH (manufactured by Kyoeisha Chemical Co., Ltd.), FS1265, SH200, SH5500, SC5540, SC5570, F-1, SD5590 (manufactured by Toray-Dow Corning Silicone Co., Ltd.); fluorine-containing antifoaming agents such as MEGAFAC F-142D, F-144D, F-178K, F-179, F-815 (manufactured by Dainippon Ink and Chemicals, Inc.), and the like can be given.

As leveling agents, Polyflow No. 7, No. 38, No. 50E, S, No. 75, No. 77, No. 85, No. 90, No. 95, No. 300, No. 460, ATF, KL-245 (manufactured by Kyoeisha Chemical Co., Ltd.), and the like can be given.

The UV curable resin compositions which are liquid at room temperature are preferable. In view of coatability, the liquid compositions having a viscosity in the range from 2 to 4000 mPa·s, and particularly from 10 to 2,000 mPa·s, are preferable.

In order to place the radically polymerizable photocurable resin composition between two disks, said composition is applied on one of the surfaces of either or both disks and the surfaces on which the composition has been applied are adhered together. There are no specific limitations to the method of applying the composition to the disks. For example, a spin coater, roll coater, screen printing, and the like are used. A coating thickness is preferably in the range from 1 to 200 μm, and preferably from 10 to 100 μm.

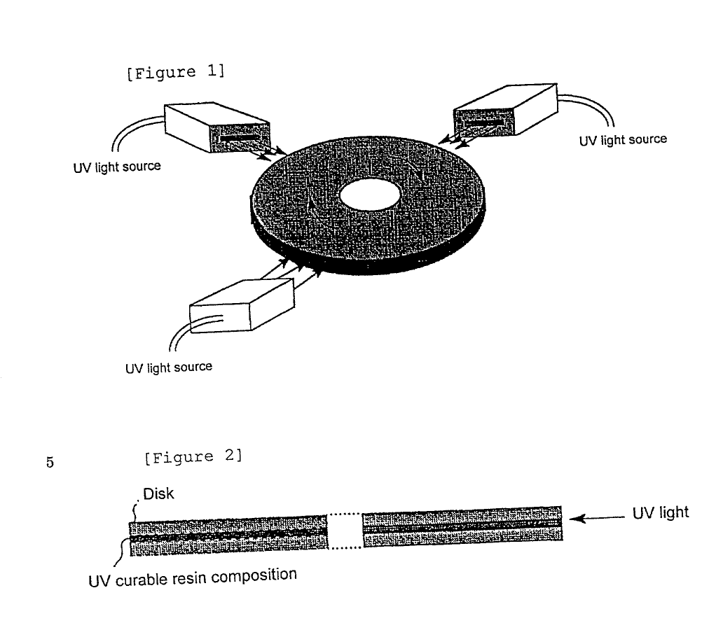

The resin composition placed between two disks is then cured by irradiation with light from the external periphery edge and/or internal periphery edge of the disks (see FIG. 1), thereby adhering the two disks. Irradiation from the external periphery edge is preferable from the viewpoint of the size of irradiation equipment, but not necessarily limited to this depending on types of equipment. A high pressure mercury lamp, metal halide lamp, xenon lamp, UV laser, and the like are used as a light source. A lamp or laser with a wavelength region from 320 nm to 450 nm is preferable.

Although light may be irradiated from one location, irradiation from two or more locations, particularly irradiation from 2-6 places outside the external peripheral edge is preferable. Rotating the two disks while irradiation (see FIG. 1) is preferable to ensure uniform and efficient cure of the resin composition.

More specifically, a method of irradiating two rotating disks with light from two or more locations outside the external peripheral edge is a typical preferable method.

High density information recording media, represented by optical disks such as DVD (digital video (or versatile) disk), MO (Magneto-Optical disk), PD (phase variable optical disk), and the like can be given as examples of information recording media fabricated by the process of the present invention.

### EXAMPLES

The present invention is now described in more detail by way of examples, which should not be construed as limiting of the present invention.

### Example 1

(1) Preparation of Radically Polymerizable Photocurable Liquid Resin (1):

A reactor equipped with a stirrer was charged with 9.15 wt % of isophorone diisocyanate, 0.03 wt % of di-n-butyl tin dilaurate, and 0.01 wt % of 2,6-di-t-butyl-p-cresol. The mixture was cooled to 5-10° C. 4.77 wt % of 2-hydroxyethyl acrylate was added dropwise while stirring the mixture to maintain the temperature at 30° C. or below. After the addition, the mixture was reacted for one hour at 30° C. Next, 20.6 wt % of polytetramethylene glycol with a number average molecular weight of 1,000 was added, followed by reaction for two hours at 50-70° C. The reaction was terminated when the amount of residual isocyanate was 0.1 wt % or less, thereby obtaining a urethane acrylate. To this urethane acrylate were added 18.75 wt % of bisphenol A epoxy diacrylate, 10.9 wt % of phenoxyethyl acrylate, 16.0 wt % of tetraethylene glycol diacrylate, 18.70 wt % of 4-hydroxybutyl acrylate, 0.1 wt % of 2,4,6-trimethylbenzoyl diphenylphosphine oxide, 1.0 wt % of γ-mercapto-n-propyltrimethoxysilane. The mixture was stirred for one hour at 50° C. to dissolution, thereby obtaining a transparent liquid resin (1) with a viscosity of 750 mPa·s at 25° C. The absorbance of light (in a 1 cm cell) at a wavelength region from 360 nm to 450 nm by this composition was 1.72. The measurement was done using a Hitachi spectrophotometer Type U-3410, with an emty 1 cm thick crystal cell as reference cell. (2) Fabrication of optical information recording media

Two disks of a polycarbonate substrate having a thickness of 0.6 mm and a diameter of 12 cm with a sputtered aluminum layer with a thickness of 100 nm were provided. The liquid resin (1) was applied on the surface of the aluminum layer of one of the disks. Immediately after the application, another disk was superposed on the aluminum layer inside. Then, while rotating the disks, an excessive liquid resin between the two disks was removed to adjust the resin thickness to 50 μm.

A metal halide lamp was installed on the same level as the liquid resin on the substrate to irradiate a cross section of the substrate with UV light at an intensity of 500 mW/cm² for 30 seconds while rotating the disks. An optical information recording medium using the liquid resin (1) as an adhesive was fabricated in this manner.

Comparative Experiment A

(1) Preparation of Slow-curing Cationically Polymerizable Photocurable Liquid Resin (2):

A reactor equipped with a stirrer was charged with Adekaoptomer KRM 2110 which is an alicyclic epoxy compound manufactured by Asahi Denka Kogyo Co., Ltd., Epolite 4000 (manufactured by Kyoeisha Chemical Co., Ltd.) which is a hydrogenated bisphenol A diglycidyl ether compound, and Sunnix Triol GP 250 (manufactured by Sanyo Chemical Industries, Ltd.) which is a polyoxypropylene glyceryl ether, in an amount of 58.8 wt %, 19.0 wt %, and 20.0 wt %, respectively. After stirring the mixture for one hour at 40° C., 2.0 wt % of Adekaoptomer SP-170 (manufactured by Asahi Denka Kogyo Co., Ltd.) which is an onium salt-type cationic photo-initiator and 0.2 wt % of Granol 400 (manufactured by Kyoeisha Chemical Co., Ltd.) which is an organic modified polysiloxane compound were added and stirred for one hour at 40° C. to dissolution, thereby obtaining a transparent liquid resin (2) with a viscosity of 410 mPa·s at 25° C.

(2) Fabrication of Optical Information Recording Media

The same disk substrates (two sheets) made from a polycarbonate with a sputtered aluminum layer as used in Example 1 were provided.

Liquid resin (2) was applied on the surface of the aluminum layer of each substrate to a thickness of 25 μm. The coatings of liquid resin (2) were irradiated with light from a metal halide lamp at an intensity of 500 mW/cm² for one minute, then the two disk substrates were superposed with the liquid resin layers inside and allowed to stand.

Adhesion strength was evaluated by detaching the two disk substrates every one minutes to find that the two disks could be detached until seven minutes after the substrates were superposed.

Therefore, according to the process of the present invention, information recording media can be manufactured easily from two disks which may not be transparent in a short period of time, for instance, one-fourteenth the time that is required for manufacturing the disks according to a conventional method.

Synthetis C1

One liter separable flask equipped with a stirrer and a thermometer was charged with 209 g of isophorone diisocyanate, 0.2 g of 3,5-di-t-butyl-4-hydroxytoluene, and 0.8 g of di-n-butyl tin dilaurate. The mixture was cooled to 10° C. over a water bath while stirring in a dry air atmosphere. Then, 109 g of 2-hydroxyethyl acrylate was added slowly over one hour and reacted while maintaining the temperature at 10-35° C. Then, 480 g of polytetramethylene glycol with a hydroxyl value of 109.7 mg KOH/g (Trade name: PTGM 1000, manufactured by Mitsubishi Chemical Corp.) was added and the reaction was continued at 40-60° C. 5 hours while stirring. The reaction product was removed to obtain urethane acrylate (C1) with a number average molecular weight of 1650.

Synthetis C2

Urethane acrylate (C2) with a number average molecular weight of 1530 was obtained in the same manner as in Synthetis (C1), except for using 472 g of polyester diol with a hydroxyl value of 111.7 mg KOH/g (Trade name: Kurapol P1010, manufactured by Kuraray Co., Ltd.) instead of polytetramethylene glycol of Synthetic Example 1.

### Examples 2-4

<Preparation of Adhesives for Optical Disks>

The components of the composition shown in Table 1 were added to and blended in a reaction vessel equipped with a stirrer, to prepare adhesives of Examples 2-4. Various components shown in Table 1 are as follows.

Component (A)

A1: 2,4,6-trimethylbenzoyldiphenylphosphineoxide (commercially available products: Lucirin TPO manufactured by BASF, molar extinction coefficient: about 490 (l/mol cm) at 400 nm).

A2: Bis(2,4,6-trimethylbenzoylphenylphosphineoxide (commercially available products: IRGACURE 819 manufactured by Ciba Specialty Chemicals Co., Ltd., molar extinction coefficient: about 660 (l/mol cm) at 400 nm.

Component (B)

B1: 1-[4-(hydroxyethoxy)-phenyl]-2-hydroxy-2-methyl-1-propan-1-one (commercially available products: IRGACURE 2959 manufactured by Ciba Specialty Chemicals Co., Ltd., molar extinction coefficient about 0 (l/mol cm) at 400 nm.

B2: 1-hydroxy-cyclohexyl phenyl ketone (commercially available products: IRGACURE 184 manufactured by Ciba Specialty Chemicals Co., Ltd., molar extinction coefficient about 0 (l/mol cm) at 400 nm.

Component (D)

D1: 4-hydroxybutyl acrylate (commercially available products: 4-HBA manufactured by Osaka organic Chemical Industry Co., Ltd.)

D2: 2-hydroxyethyl acrylate (commercially available products: HEA manufactured by Osaka Organic Chemical Industry Co,. Ltd.).

Component (E)

E1: Pentaerythritol tetraacrylate (commercially available products: KAYARAD DPHA manufactured by Nippon Kayaky Co., Ltd.)

E2: Trimethylolpropane triacrylate (commercially available products: Viscoat 295 manufactured by Osaka Organic Chemical industry Co., Ltd.)

Deep curability and irradiated edge curability of the above adhesives (adhesives of Examples 2-4 were evaluated as follows.

1. Deep Curability

Two sheet of aluminium substrates prepared by performing sputtering on PC substrates were attached together using a spin coater so as to produce coating film with a thickness of 50 μm. The two substrates were caused to adhere by irradiating the side of the rotating disk in the equipment shown in FIG. 1 with light at a dose of 3000 mJ/cm² from high pressure mercury vapor lamps. The attached disks were peeled off to observe if there is an uncured portion of the liquid composition left inside. If there was such an uncured portion, the resin composition was judged to exhibit bad deep curability and marked X. If there was no uncured liquid portion observed, the resin composition was judged to exhibit good deep curability and marked ∘ in Table 1.

2. Irradiated Edge Curability

Edges of the irradiated area of adhered disks prepared in 1 above was touched to check if there was any tackiness. When tackiness was felt, the resin composition was judged to exhibit bad irradiated edge curability and marked X. If no tackiness was felt, the resin composition was judged to exhibit good irradiated edge curability and marked in table 1 with ∘.

The results evaluation on the resin compositions prepared in Examples and Comparative Experiments are shown in Table 1. It can be seen from the results that both the resin compositions of Examples 2 to 4 exhibit excellent deep curability and irradiated edge curability.

| | Example | | |
|---|---|---|---|
| Component | 2 | 3 | 4 |
| A1 | | 0.04 | 0.03 |
| A2 | 0.02 | | |
| B1 | 3 | | 4 |
| B2 | | 3 | |
| C1 | 50 | | 40 |
| C2 | | 40 | |
| D1 | 45 | | |
| D2 | | 50 | 50 |
| E1 | 5 | | 10 |
| E2 | | 10 | |
| Deep curability | ∘ | ∘ | ∘ |
| Irradiated edge | ∘ | ∘ | ∘ |
| curability | | | |

Effect of Invention

High quality information recording media can be manufactured according to the process of the present invention by efficiently adhering two disks in a short period of time, whether or not the two disks are transparent. The process is highly advantageous for manufacturing information recording media on an industrial scale.

1. A process for manufacturing information recording media by adhering two or more disks, at least one of which possesses an information recording layer, wherein a radically polymerizable photocurable resin composition is put between at least two disks and the resin composition is cured to adhere the disks by irradiating light from the external periphery edge and/or internal periphery edge of said disks, wherein the radically polymerizable photocurable resin composition has a light absorbance of 12.0 or less at a wavelength region from 360 nm to 450 nm.

2. The process according to claim 1, wherein said radically polymerizable photocurable resin composition comprises an oligomer, reactive diluent, radically polymerizable photo-initiator, and optionally additive.

3. The process according to any one of claims 1-2 wherein the light absorbance of the composition is 9.0 or less.

4. The process according to any one of claims 1-3 wherein the composition comprises a photoinitiator having a large molar extinction coefficient at a wavelength in the range from 400 to 450 nm.

5. The process according to claim 4, wherein the molar extinction coefficient is 50 (l/mol cm) or more.

6. The process according to any one of claims 4-5 wherein the photoinitiator is present in an amount from 0.001 to 1 wt %.

7. The process according to any one of claims 4-6 wherein the composition further comprises a photoinitiator having a small molar extinction coefficient at a wavelength in the range from 400-450 nm.

8. The process according to claim 7 wherein the molar extinction coefficient of the further photoinitiator is 1 (l/mol cm) or less.

9. The process according to any one of claims 7-8 wherein the further photoinitiator is present in an amount of 0.1-20 wt %.

10. An information recording medium obtainable by a process according to any one of claims 1-9

11. A photocurable resin composition, which is suitable as an adhesive for the manufacture of high density information recording media, containing an oligomer, reactive diluent, a photoinitiator and optionally an additive, where the composition has a light absorbance of 12.0 or less, measured at a wavelength region from 360 nm to 450 nm and the photoinitiator has a large molar extinction coefficient at a wavelenght in the range from 400 to 450 nm.

12. A resin compostion according to claim 11, characterized in that it contains another photoinitiator with a small molar extinction coefficient at a wavelenght in the range from 400 to 450 nm.
